(19) United States
(12) Patent Application Publication
(10) Pub. No.: US 2015/0171097 A1
(43) Pub. Date: Jun. 18, 2015

(54) NONVOLATILE MEMORY DEVICES AND METHODS OF FORMING THE SAME

(71) Applicants: JEEHOON HAN, HWASEONG-SI (KR); YOON HEE KIM, SUWON-SI (KR); JI SUN PARK, SUWON-SI (KR); WANGCHUL SHIN, SUWON-SI (KR)

(72) Inventors: JEEHOON HAN, HWASEONG-SI (KR); YOON HEE KIM, SUWON-SI (KR); JI SUN PARK, SUWON-SI (KR); WANGCHUL SHIN, SUWON-SI (KR)

(21) Appl. No.: 14/484,977

(22) Filed: Sep. 12, 2014

(30) Foreign Application Priority Data
Dec. 16, 2013 (KR) 10-2013-0156522

(51) Int. Cl. H01L 27/115; H01L 29/49; H01L 29/788; H01L 29/423

(52) U.S. Cl. CPC H01L 27/11524; H01L 29/42328; H01L 29/4916; H01L 27/11529; H01L 29/7883

(57) ABSTRACT

A nonvolatile memory device has select gates on a semiconductor substrate and cell gates on the semiconductor substrate between the select gates. Each of the cell gates includes a floating gate pattern on the semiconductor substrate, a tunnel insulating pattern interposed between the floating gate pattern and the semiconductor substrate, a blocking insulating pattern on the floating gate pattern, and a control gate pattern on the blocking insulating pattern. The control gate pattern includes a first control gate pattern, a second control gate pattern on the first control gate pattern, a cell conductive pattern on the second control gate pattern, and a barrier pattern interposed between the first control gate pattern and the second control gate pattern. Each of the select gates may have patterns similar to those of the cell gates.

### PRIORITY STATEMENT

This U.S. nonprovisional patent application claims priority under 35 U.S.C. §119 of Korean Patent Application 10-2013-0156522 filed on Dec. 16, 2013, the entire contents of which are hereby incorporated by reference.

### BACKGROUND

The present inventive concept relates to semiconductor devices. More particularly, the inventive concept relates to nonvolatile memory devices and methods of forming the same.

Nonvolatile memory devices retain their stored data when their power supplies are interrupted. Current demands in the electronics industry require that nonvolatile memory devices are highly integrated and operate at high speeds. For this purpose, a metal whose electrical resistance is less than that of polysilicon is used as the material of the gate electrode of nonvolatile memory devices.

Flash memory devices including floating gates are typical examples of nonvolatile memory devices. The flash memory devices are highly integrated devices which have been developed to combine benefits of EPROM (Erasable Programmable Read Only Memory) and EEPROM (Electrically Erasable Programmable Read Only Memory) devices. Flash memory devices can store data of logic “0” or “1” by an injecting of charges into the floating gates or a releasing of charges from the floating gates.

### SUMMARY

According to an aspect of the inventive concept, there is provided a nonvolatile memory device which includes a semiconductor substrate, select gates on the semiconductor substrate, and cell gates on the semiconductor substrate, and in which the cell gates are interposed between the select gates, in which each of the cell gates includes a tunnel insulating pattern on the semiconductor substrate, a floating gate on the tunnel insulating pattern, a blocking insulating pattern on the floating gate, and a control gate on the blocking insulating pattern, and in which the control gate includes a first control gate pattern, a second control gate pattern on the first control gate pattern, a cell conductive pattern on the second control gate pattern, and a barrier pattern interposed between the first control gate pattern and the second control gate pattern.

According to another aspect of the inventive concept, there is provided a nonvolatile memory device which includes a semiconductor substrate, a lower gate pattern on the semiconductor substrate, a gate dielectric pattern interposed between the lower gate pattern and the semiconductor substrate, an inter-gate dielectric pattern and a first upper gate pattern stacked on the lower gate pattern and together defining an opening leading to the lower gate pattern, a second upper gate pattern on the first upper gate pattern, and a conductive pattern on the second upper gate pattern, and in which the second upper gate pattern and the conductive pattern protrude into the opening, and the bather pattern is interposed between the lower gate pattern and the second upper gate pattern.

According to still another aspect of the inventive concept, there is provided a nonvolatile memory device including a plurality of cell strings in a cell region of the device, and a peripheral transistor in a peripheral region of the device located outside the cell region, and in which the cell strings include memory cell transistors and select transistors, the transistors of the cell strings are constituted by gate structures disposed in an array on a semiconductor substrate, and each of the gate structures of the memory cell transistors, of the select transistors and/or of the peripheral transistor comprises a gate dielectric layer disposed on the semiconductor substrate, a lower gate structure disposed on the gate dielectric layer and comprising a polysilicon layer containing a dopant, and an upper gate structure disposed on the polysilicon layer, and in which the upper gate structure includes a first upper gate layer, a second upper gate layer, a silicon oxide layer interposed between the first and second upper gate layers, and a conductive layer comprising a metal disposed on the second upper gate layer.

According to still another aspect of the inventive concept, there is provided a method of forming a nonvolatile memory device, and which includes sequentially forming a first insulating layer, a lower gate layer, a second insulating layer, and a first upper gate layer on a semiconductor substrate, etching the second insulating layer and the first upper gate layer to form a plurality of openings each exposing a portion of the lower gate layer, forming a barrier layer on the first gate layer and the exposed portion of the lower gate layer, and sequentially forming a second gate layer and a conductive layer on the barrier layer.

### BRIEF DESCRIPTION OF THE DRAWINGS

The foregoing and other features and advantages of the inventive concept will be apparent from the more detailed description of the preferred embodiments of inventive concepts, made below with reference to the accompanying drawings. The drawings are not necessarily to scale, emphasis instead being placed upon illustrating the principles of inventive concept. In the drawings:

FIG. 1 is a schematic diagram illustrating a nonvolatile memory device according to the present inventive concept;

FIG. 2 is a block diagram illustrating a nonvolatile memory device according to the present inventive concept;

FIG. 3 is a circuit illustrating a memory cell array of a nonvolatile memory device according to the present inventive concept;

FIG. 4 is a plan view illustrating a nonvolatile memory device according to the present inventive concept;

FIG. 5A is a cross-sectional view taken along lines I-I′, II-II′, and III-III′ of FIG. 4;

FIG. 5B is an enlarged view of portion “A” of the device shown in FIG. 5A;

FIG. 5C is an enlarged view of portion “B” of the device shown in FIG. 5A;

FIG. 5D is an enlarged view of portion “C” of the device shown in FIG. 5A;

FIGS. 6, 7 and 8 are graphs illustrating resistance characteristics of select gates;

FIGS. 9A, 10A, 11A, 12A and 13A together illustrate a method of fabricating the nonvolatile memory device of FIG. 4 according to the present inventive concept and are cross-sectional views, taken along lines I-I′, II-II′ and III-III′ of FIG. 4, during the course of manufacture of the nonvolatile memory device,

FIGS. 9B, 10B, 11B, 12B and 13B are enlarged views of sections A of FIGS. 9A, 10A, 11A, 12A and 13A, respectively;

FIGS. 9C, 10C, 11C, 12C and 13C are enlarged views of sections B of FIGS. 9A, 10A, 11A, 12A and, respectively;

FIGS. 9D, 10D, 11D, 12D and 3D are enlarged views of sections C of FIGS. 9A, 10A, 11A, 12A and 13A, respectively;

FIG. 14 is a schematic block diagram illustrating an electronic system including an embodiment of a nonvolatile memory device, according to the present inventive concept;

FIG. 15 is a schematic block diagram illustrating an example of a memory system including an embodiment of a nonvolatile memory device, according to the present inventive concept; and

FIG. 16 is a schematic block diagram illustrating an example of a data processing system including an embodiment of a nonvolatile memory device, according to the present inventive concept.

### DETAILED DESCRIPTION OF THE PREFERRED EMBODIMENTS

Various embodiments and examples of embodiments of the inventive concept will be described more fully hereinafter with reference to the accompanying drawings. In the drawings, the sizes and relative sizes and shapes of elements, layers and regions shown in section may be exaggerated for clarity. In particular, the cross-sectional illustrations of the semiconductor device and intermediate structure fabricated during the course of its manufacture are schematic. Also, like numerals are used to designate like elements throughout the drawings.

It will be understood that although the terms first, second, third etc. are used herein to describe various elements, layers, etc., these elements and/or layers are not limited by these terms. These terms are only used to distinguish one element or layer from another.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. The term “connected” will generally refer to an electrical connection unless the context in which the term is used suggests otherwise. The term “about” as used in a range will generally refer that slight deviations from the endpoint(s) of the range are allowed for within the tolerance of the process parameters selected to provide a value corresponding to the endpoint.

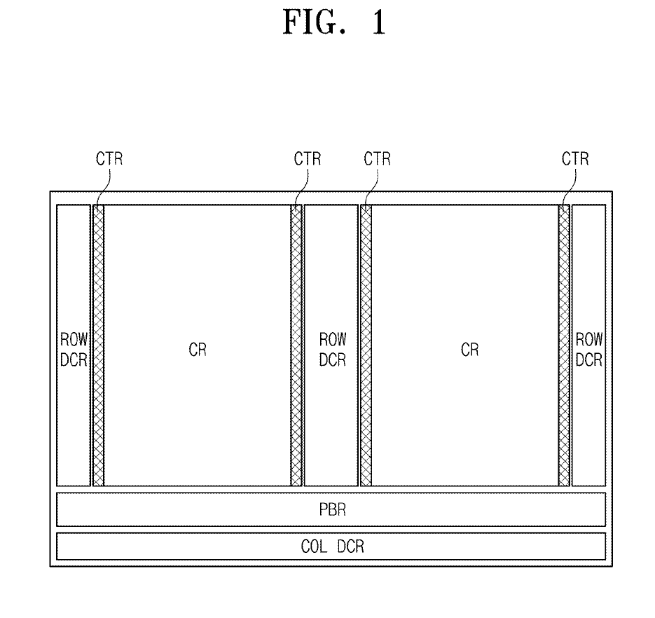

Referring to FIG. 1, a nonvolatile memory device comprises a cell region CR and a peripheral region. The peripheral region may include a row decoder region ROW DCR, a page buffer region PBR, and a column decoder region COL DCR. A contact region CTR may also be provided between the cell region CR and the row decoder region ROW DCR. In the illustrated example, the nonvolatile memory device has a plurality of cell regions CR, a plurality of row decoder regions ROW DCR, and a respective contact region CTR interposed between each cell region CR and a row decoder region ROW DCR adjacent thereto.

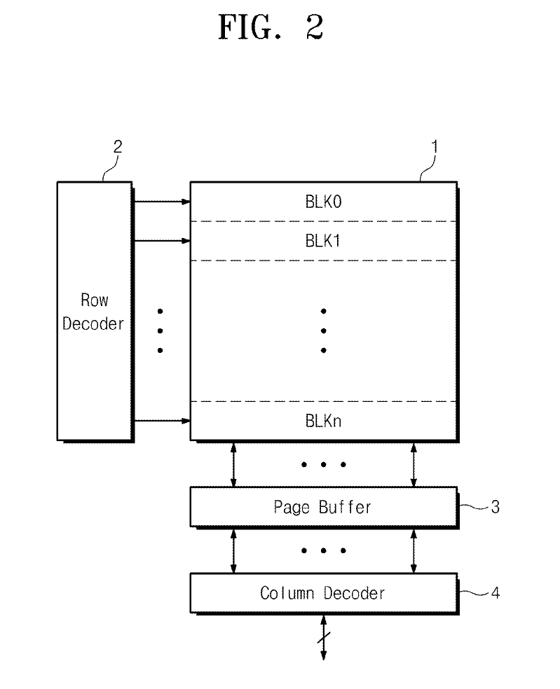

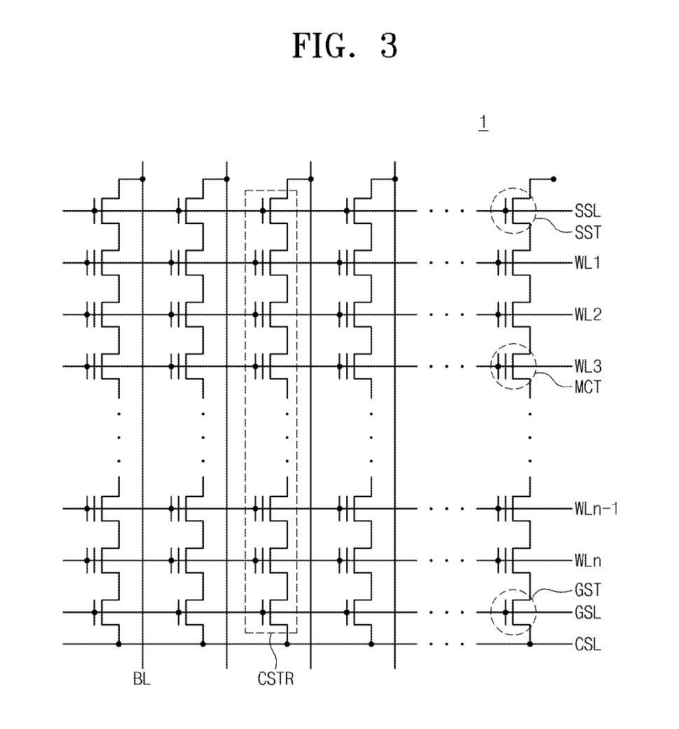

Referring to FIGS. 1 and 2, the cell region CR contains a memory cell array 1 including a plurality of memory cells. The memory cell array 1 may also include a plurality of word lines, a plurality of bit lines, and the plurality of memory cells are electrically connected to the plurality of word and the bit lines. The memory cell array 1 may also include a plurality of memory blocks BLK0˜BLKn that are data erase units. The memory cell array 1 will be described in detail later with reference to FIG. 3.

The row decoder region ROW DCR includes a row decoder 2 configured to select the word lines of the memory cell array 1. The contact region CTR may include an interconnection structure configured to electrically connect the memory cell array 1 and the row decoder 2 to each other. The row decoder 2 serves to select one of the memory blocks BLK0˜BLKn of the memory cell array 1 and select one of the word lines of the selected memory block according to address information. To this end, the row decoder 2 may provide word line voltages generated from a voltage generating circuit (not shown) to the selected word line and unselected word lines in response to the control of a control circuit (also not shown).

The page buffer region PBR includes a page buffer 3 configured to read information stored in the memory cells. The page buffer 3 may temporarily store data that will be stored in memory cells or sense data stored in the memory cells according to operation modes. More specifically, the page buffer 3 may be operated as a write driver circuit during a program operation mode and operated as a sense amplifier circuit during a read operation mode.

The column decoder region COL DCR includes a column decoder 4 connected to the bit lines of the memory cell array 1. The column decoder 4 may provide a data transfer path between the page buffer 3 and an external device (e.g., a memory controller).

FIG. 3 shows an example of a circuit provided by the memory cell array 1 of the nonvolatile memory device according to the present inventive concept. In this example, the nonvolatile memory device is a NAND type of Flash memory device.

Referring to FIG. 3, the cell array of this example includes a common source line CSL, a plurality of bit lines BL, and a plurality of cell strings CSTR between the common source line CSL and the bit lines BL.

The bit lines BL are disposed in parallel and occupy a two-dimensional space (i.e., are disposed in the same plane) and each of the cell strings CSTR is connected to a respective one of the bit lines BL. The cell strings CSTR are also connected in common to the common source line CSL. That is, the cell strings CSTR are interposed between the plurality of bit lines BL and one common source line CSL.

Also, in this example, each of the cell strings CSTR includes a ground select transistor GST connected to the common source line CSL, a string select transistor SST connected to one bit line BL, and a plurality of memory cell transistors MCT between the ground select transistor GST and the string select transistor SST. The ground select transistor GST, the string select transistor SST, and the memory cell transistors MCT are connected in series.

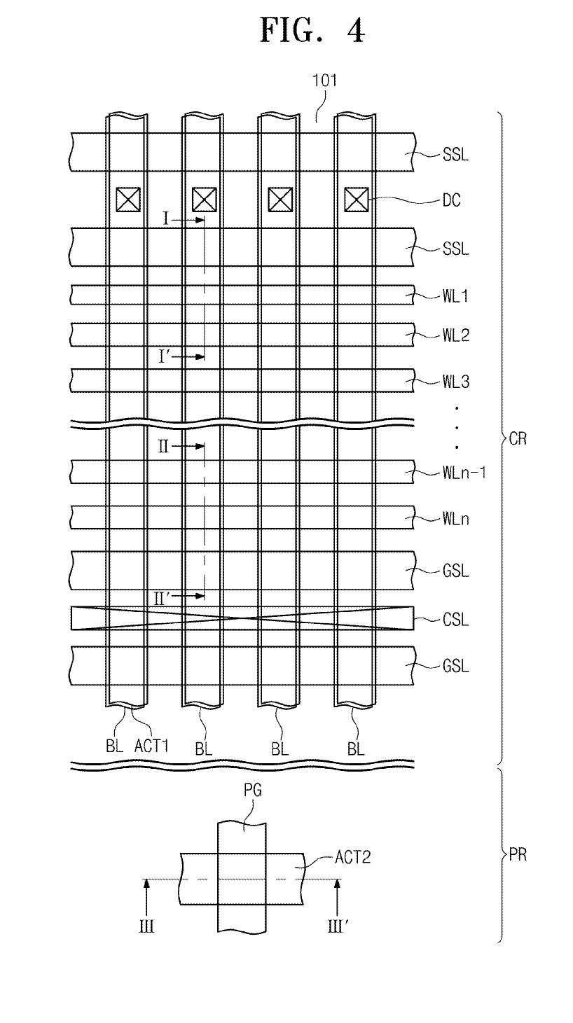

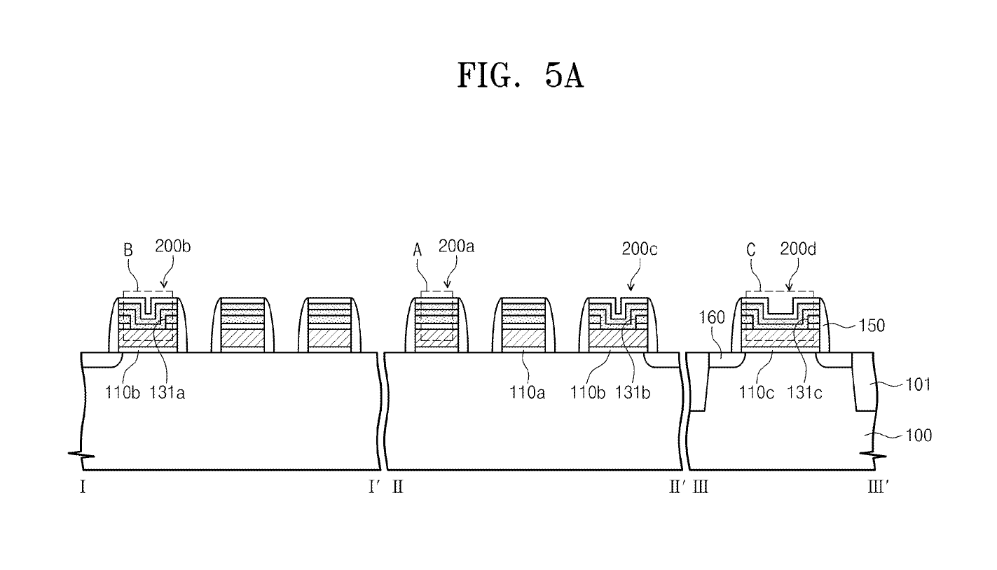

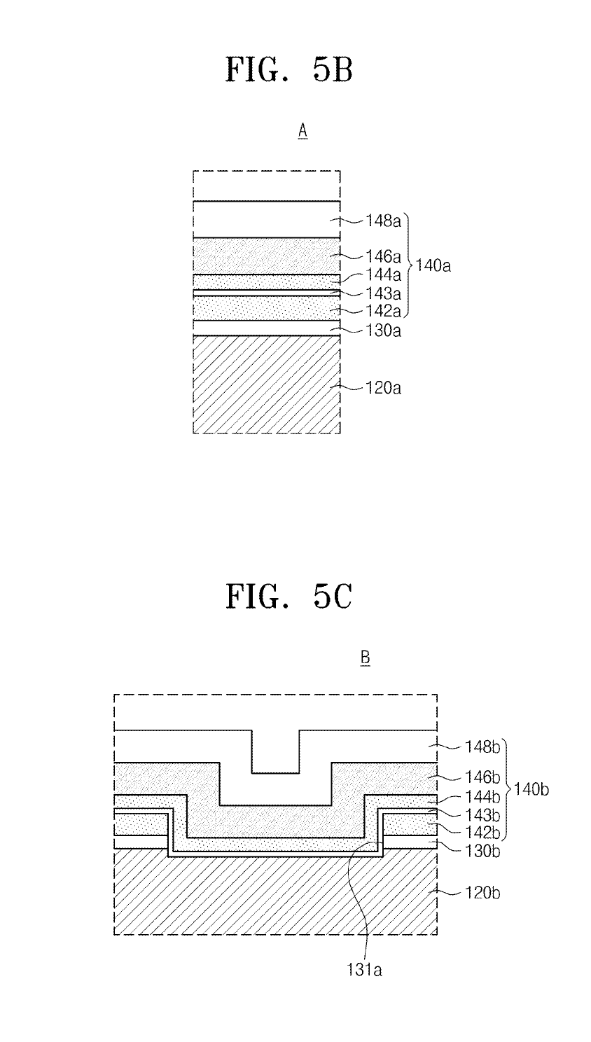

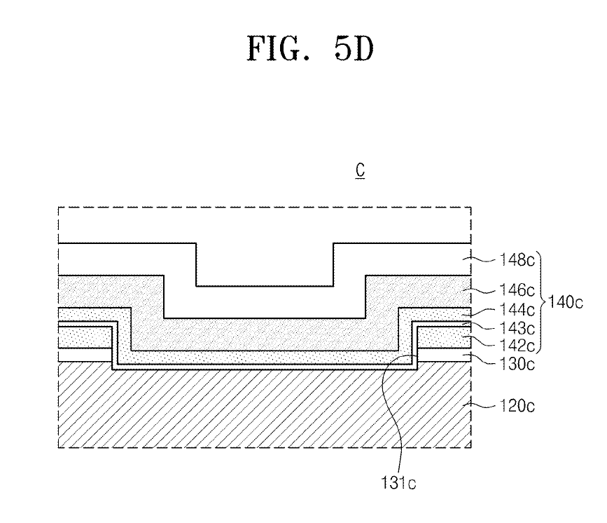

Referring to FIG. 4 and FIGS. 5A to 5C, an embodiment of the nonvolatile memory device according to the inventive concept has a semiconductor substrate 100 selected from the group consisting of a single crystalline silicon layer, a SOI (silicon on insulator), a silicon layer on a silicon germanium layer, and a polysilicon layer on an insulating layer, for example. A device isolation layer 101 is disposed in the semiconductor substrate 100 to define cell active regions ACT1 and a peripheral region ACT2.

In the cell region CR, at least one string select line SSL and at least one ground select line GSL may extend parallel to one another across the cell active regions ACT1. A plurality of word lines WL1˜WLn may be arranged between the string select line SSL and the ground select line GSL. Contact plugs DC may be provided between adjacent string select lines SSL to electrically connect the cell active regions ACT1 to the bit lines BL. The common source line CSL may be provided between adjacent ground select lines GSL. In the peripheral region PR, a peripheral gate PG may be provided on the peripheral active region ACT2.

The nonvolatile memory device may also include a string select gate 200b, a ground select gate 200c, and a plurality of memory cell gates 200a provided on the semiconductor substrate 100 of the cell region CR. The plurality of memory cell gates 200a may be arranged between the string select gate 200b and the ground select gate 200c. Each of the memory cell gates 200a may include a tunnel insulating pattern 110a, a floating gate 120a, a blocking insulating pattern 130a, and a control gate 140a. The control gate 140a may include a first control gate pattern 142a, a second control gate pattern 144a on the first control gate pattern 142a, and a cell conductive pattern 146a on the second control gate pattern 144a. The control gate 140a may further include a first barrier pattern 143a between the first control gate pattern 142a and the second control gate pattern 144a. For ease of illustration, the first barrier pattern 143a is omitted in FIG. 5A. A cell capping pattern 148a may be provided on the cell conductive pattern 146a.

The string select gate 200b and the ground select gate 200c may have structural features similar to those of the memory cell gates 200a. For example, the string select gate 200b may include a gate dielectric pattern 110b, a lower gate 120b, an inter-gate dielectric pattern 130b, and an upper gate 140b. The upper gate 140b may include a first upper gate pattern 142b, a second upper gate pattern 144b on the first upper gate pattern 142b, and a select conductive pattern 146b on the second upper gate pattern 144b. A select capping pattern 148b may be provided on the select conductive pattern 146b.

The inter-gate dielectric pattern 130b and the first upper gate pattern 142b may have a first opening 131a which exposes the lower gate 120b. A portion of the lower gate 120b exposed by the first opening 131a may have a level lower than an upper surface of the lower gate 120b. The second upper gate pattern 144b and the select conductive pattern 146b may extend inside the first opening 131a. A second bather pattern 143b may be provided between the first upper gate pattern 142b and the second upper gate pattern 144b. The second barrier pattern 143b may extend along sides of the first opening 131a as interposed between the second upper gate pattern 144b and the lower gate 120b. The second upper gate pattern 144b may be electrically connected to the lower gate 120b exposed by the first opening 131a where the second barrier pattern 143b is interposed between the second upper gate pattern 144b and the lower gate 120b. For ease of illustration, the second barrier pattern 143b is omitted in FIG. 5A.

The tunnel insulating pattern 110a and the gate dielectric pattern 110b may comprise a silicon oxide layer. The floating gate 120a and the lower gate 120b may comprise a polysilicon layer. The floating gate 120a and the lower gate 120b may also include an impurity, for example, boron at a concentration of about 4×10²⁰ atoms/m³. The blocking insulating pattern 130a and the inter-gate dielectric pattern 130b may comprise at least one layer selected from the group consisting of a layer of a silicon oxide, a silicon nitride, Al₂O₃, hafnium aluminate, HfAlO, HfAlON, hafnium silicate, HfSiO, and HfSiON. The blocking insulating pattern 130a and the inter-gate dielectric pattern 130b may each be composed of, for example, a silicon oxide layer, a silicon nitride layer, and a silicon oxide layer stacked in the foregoing order on one another.

The first control gate pattern 142a and the first upper gate pattern 142b may comprise a polysilicon layer. The second control gate pattern 144a and the second upper gate pattern 144b may comprise a polysilicon layer. The first control gate pattern 142a may have a thickness greater than that of the second control gate pattern 144a. Likewise, the first upper gate pattern 142b may have a thickness greater than that of the second upper gate pattern 144b. Each of the first control gate pattern 142a and the first upper gate pattern 142b may have a thickness of about 200 Å to about 300 Å. The second control gate pattern 144a and the second upper gate pattern 144b may have a thickness of about 100 Å or less. The cell conductive pattern 146a and the select conductive pattern 146b may comprise at least one material selected from the group consisting of metals (e.g., tungsten, cobalt, or molybdenum), conductive metal nitrides (e.g., tungsten nitride, titanium nitride, tantalum nitride, or molybdenum nitride), and metal silicides (e.g., tungsten silicide or cobalt silicide). For example, the cell conductive pattern 146a and the select conductive pattern 146b may each consist of tungsten nitride and tungsten on the tungsten nitride.

The cell capping pattern 148a and the select capping pattern 148b may each be a silicon nitride layer.

The ground select gate 200c may be structurally identical to the string select gate 200b. In particular, the ground select gate 200c may include a second opening 131b similar in form and function to the opening 131a of the string select gate 200b. Thus, a detailed description of features of the ground select gate 200c that are similar to those of the string select gate 200b may be omitted for the sake of brevity.

The first and second barrier patterns 143a and 143b may be formed of the same material. For example, the first and second barrier patterns 143a and 143b may each be a silicon oxide layer. The second barrier pattern 143b may prevent an impurity (e.g., boron) contained in the lower gate pattern 120b from diffusing into the select conductive pattern 146b. If an impurity (e.g., boron) were to diffuse into the select conductive pattern 146b, a high resistive material (e.g., a tungsten-boron compound or a tungsten-boron-nitrogen compound) could form in the select conductive pattern 146b. The forming of such a high resistive material would, in turn, increase an interface resistance between the upper gate pattern 144b and the select conductive pattern 146b. Moreover, the resistances of the select gates 200b and 200c would be increased as well.

For these reasons, according to an aspect of the inventive concept, the first and second barrier patterns 143a and 143b minimize resistance between the first control gate pattern 142a and the second control gate pattern 144a and between the second upper gate pattern 144b and the lower gate pattern 120b. To this end, each of the first and second barrier patterns 143a and 143b, formed of a silicon oxide layer, may have a thickness in a range of about 10 Å to about 20 Å and preferably in a range of about 10 Å to about 15 Å. If the thickness of the silicon oxide layer were less than 10 Å, the first and second barrier patterns 143a and 143b would not be able to prevent the impurity (e.g., boron) contained in the lower gate pattern 120b from diffusing into the select conductive pattern 146b. If the thickness of the silicon oxide layer were greater than 10 Å, the silicon oxide layer could provide too sharp of an increase in resistance between the first control gate pattern 142a and the second control gate pattern 144a and between the second upper gate pattern 144b and the lower gate pattern 120b.

The nonvolatile memory device may also include a peripheral gate 200d on the semiconductor substrate 100 in the peripheral region PR. The peripheral gate 200d may be structurally identical or similar to the string select gate 200b and the ground select gate 200c. For example, the peripheral gate 200d may include a lower gate 120c and an upper gate 140c on the semiconductor substrate 100. A gate dielectric pattern 110c may be interposed between the lower gate 120c and the semiconductor substrate 120c. The upper gate 140c may include an inter-gate dielectric pattern 130c and a first upper gate pattern 142c that are stacked in that order on the lower gate 120c and which define a third opening 131c exposing the lower gate 120c, a second upper gate pattern 144c on the first upper gate pattern 142c, and a peripheral conductive pattern 146c on the second upper gate pattern 142c. The second upper gate pattern 144c and the peripheral conductive pattern 146c may extend within the third opening 131c, and a third barrier layer 143c may be provided between the lower gate pattern 120c and the second upper gate pattern 144c. A peripheral capping pattern 148c may be provided on the peripheral conductive pattern 146c. Other features/aspects of the peripheral gate 200d that are similar to those of the string select gate 200b and the ground select gate 200c will not be described in detail for the sake of brevity. Also, for ease of illustration, the third barrier pattern 143c is omitted in FIG. 5A.

Referring still to FIG. 5A, sidewall spacers 150 may be disposed on sidewalls of the gates 200a, 200b, 200c, and 200d. Impurity regions 160 may be formed in the semiconductor substrate 100 at one or both sides of at least one of the gates 200a, 200b, 200c, and 200d.

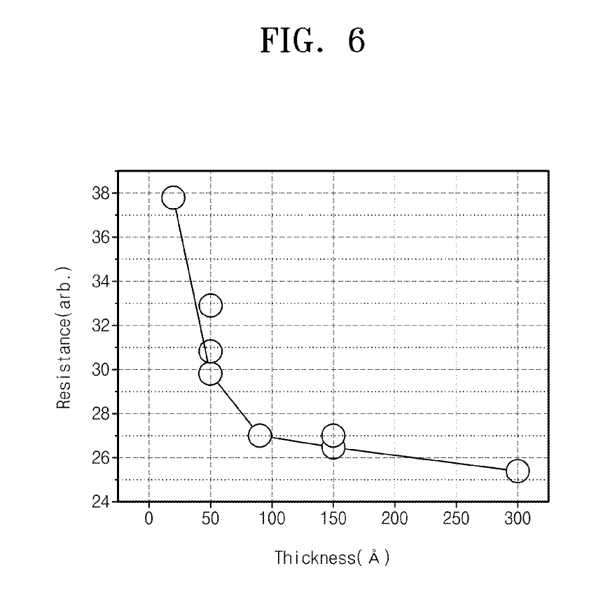

Electrical characteristics of the string select gate 200b will be described hereinafter with reference to FIGS. 6-8. Electrical characteristics of the ground select gate 200c and the peripheral gate 200d may be identical to those of the string select gate 200b.

FIG. 6 shows resistances in string select gates corresponding to those shown in FIG. 5C, but in cases in which the second barrier pattern 143b is omitted, i.e., in cases in which the lower gate 120b and the second upper gate pattern 144b are connected. The resistances are those between the lower gate pattern 120b and the select conductive pattern 146b. As FIG. 6 shows, the resistance starts to rise as the thickness of the second upper gate pattern 144b becomes less than 100 Å and begins to dramatically increase as the thicknesses of the second upper gate 144b becomes less than 50 Å. The increase of resistance is caused by the diffusion of boron in the lower gate pattern 120b into the select conductive pattern 146b, as described earlier. In other words, if the second upper gate pattern 144b is relatively thick, the second upper gate pattern 144b can prevent the diffusion of boron. However, forming the second upper gate pattern 144b to a relatively great thickness compromises the degree to which the nonvolatile memory device can be integrated. That is, it is inevitable that the thickness of the second upper gate pattern 144b must be minimized if a required degree of integration is to be realized. Accordingly, the thickness of the second upper gate pattern 144b can not be used as a means in and of itself to keep certain resistances in the device in check.

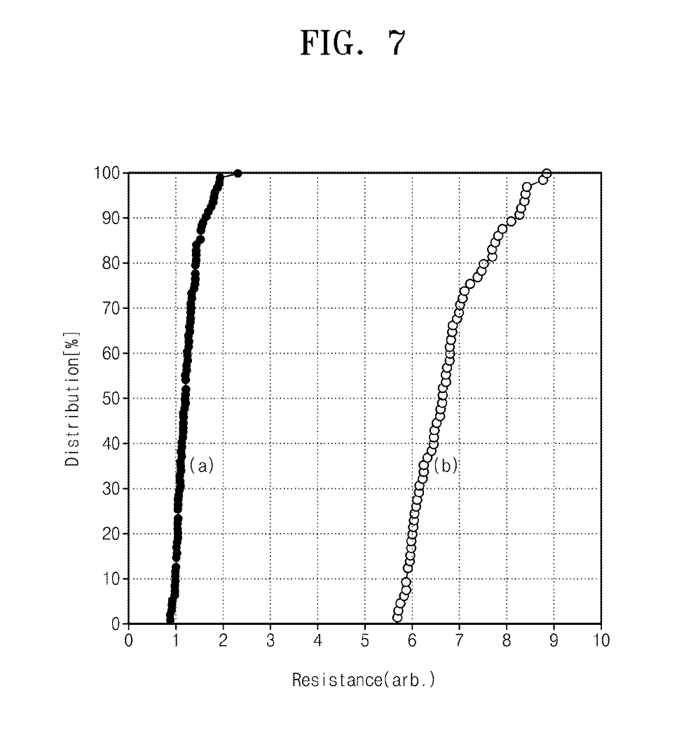

In FIG. 7, a trace (a) shows the resistance between the lower gate 120b and the select conductive pattern 146b in the case in which a silicon oxide layer having a thickness of 15 Å is used as the second barrier pattern 143b, while a trace (b) shows the resistance between the lower gate pattern 120b and the select conductive pattern 146b in a comparative example in which the second barrier pattern 143b has been removed. In this latter case, the silicon oxide layer was completely removed by SC1 (NH4OH+H2O2+H2O) or 200:1 HF solution before the formation of the second upper gate pattern 144b. Also, in the devices used to produce the results shown in FIG. 7, the boron concentration of the lower gate pattern 120b was about 4×10²⁰ atoms/m^{3,} and the thickness of the second upper gate pattern 144b was about 50 Å, as was described with reference to FIGS. 4 and 5A to 5C.

As shown in FIG. 7, the resistance (a) between the lower gate 120b and the select conductive pattern 146b is more than 6 times less than the resistance (b) between the corresponding layers of the comparative example.

Thus, electrical characteristics of a nonvolatile memory device may be improved according to an aspect of the present inventive concept.

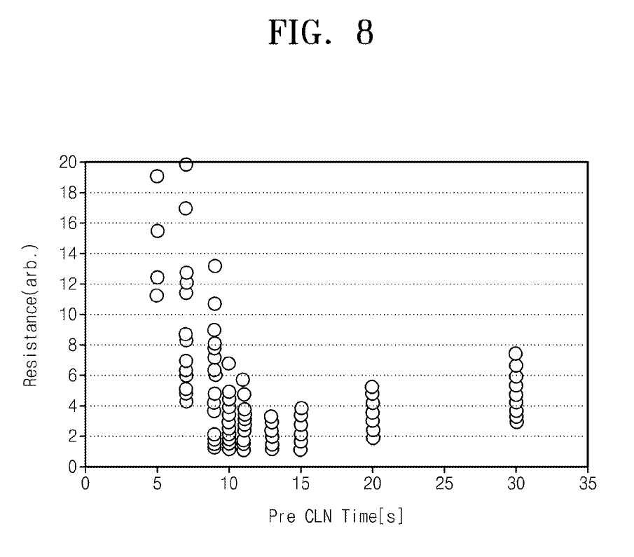

FIG. 8 shows resistances between the lower gate 120b and the select conductive pattern 146b according to the thickness of a silicon oxide layer used as the second barrier pattern 143b.

A native silicon oxide layer may be formed on the lower gate 120b and the select conductive pattern 146b during the formation of the first opening 131a by patterning the inter-gate dielectric pattern 130b and the first upper gate pattern 142b as illustrated in FIG. 5C. Generally, a process of removing the native silicon oxide layer is performed to decrease resistance between the lower gate pattern 120b and the select conductive pattern 146b. A 200:1 HF solution may be used to remove the native silicon oxide layer.

Therefore, a 200:1 HF solution may be used in a pre-cleaning process to adjust the thickness of silicon oxide layer. When the pre-cleaning process is performed for about 10 seconds, the silicon oxide layer may have a thickness of about 20 Å. When the pre-cleaning process is performed for about 20 seconds, the silicon oxide layer may have a thickness of about 10 Å. In other words, the silicon oxide layer may be formed to a thickness of greater than about 20 Å by performing the pre-cleaning process for less than 10 seconds, whereas the silicon oxide layer may be formed to a thickness of less than about 10 Å by performing the pre-cleaning process for over 20 seconds.

As depicted in FIG. 8, the resistance between the lower gate pattern 120b and the select conductive pattern 146b sharply jumps as the thickness of silicon oxide layer becomes greater than 20 Å, i.e., the pre-cleaning is performed within 10 seconds. This shows that a thickness in this range for a silicon oxide layer, if used as the second barrier layer 143b, would be too great. On the other hand, the resistance between the lower gate pattern 120b and the select conductive pattern 146b rises as the thickness of silicon oxide layer decreases below 10 Å, i.e., when the pre-cleaning is performed for over 20 seconds. This shows that a thickness in this range for a silicon oxide layer, if used as the second barrier layer 143b, would be too small to prevent boron of the lower gate pattern 120b from diffusing into the select conductive pattern 146b. Accordingly, it is preferable that a silicon oxide layer used as the second barrier pattern 143b have a thickness of about 10 Å to about 20 Å. More preferably, the silicon oxide layer as the second barrier pattern 143b has a thickness of about 10 Å to about 15 Å

The silicon oxide layer used as the second barrier pattern 143b may include different layers from the native oxide layer, for example, a deposition layer formed by a chemical vapor deposition. The second barrier layer 143b may be not limited to the silicon oxide layer but may include various layers.

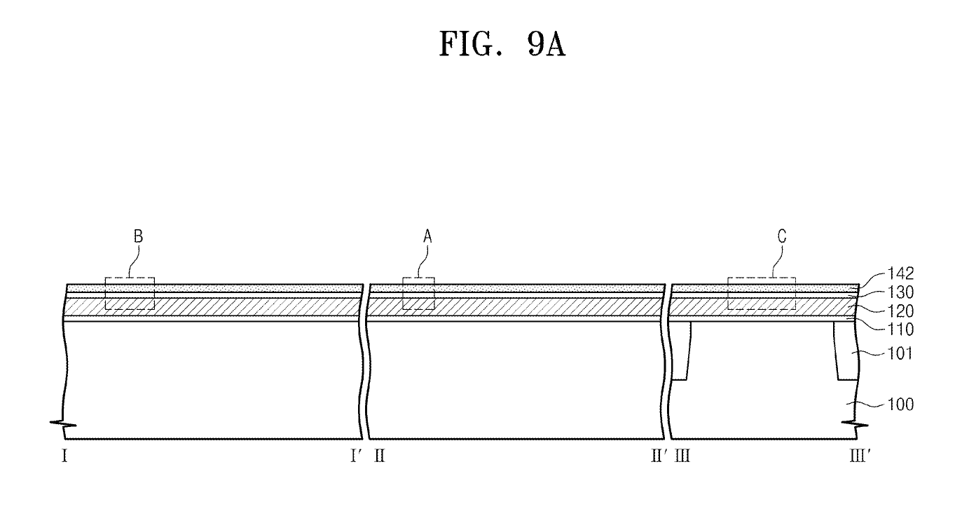

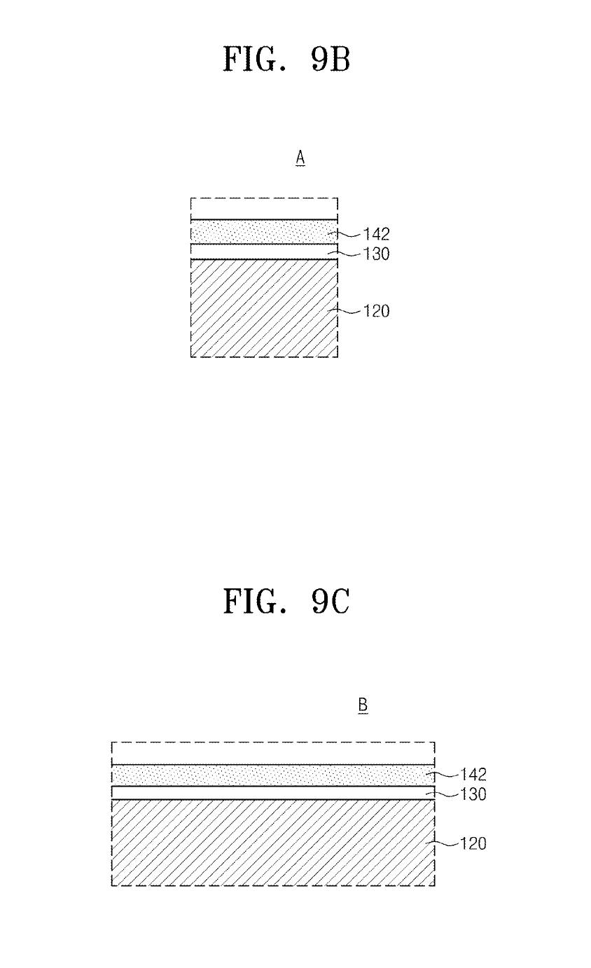

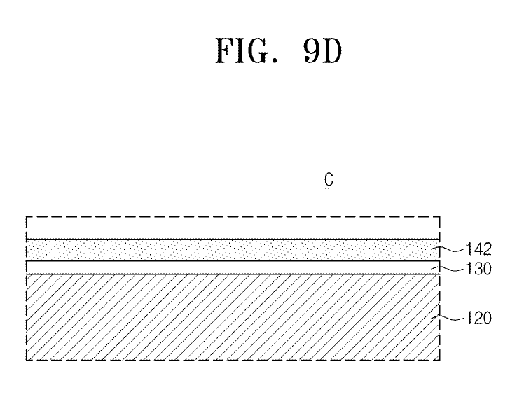

A method of forming a nonvolatile memory device according to the present inventive concept will now be described in detail with further reference to FIGS. 9A-13D.

Referring to FIG. 4 and FIGS. 9A to 9D, a hard mask, for example and not shown, is formed on a semiconductor substrate 100 including over a cell region CR and a peripheral region PR. The hard mask may include a material having an etch selectivity with respect to the semiconductor substrate 100. For example, the hard mask may comprise a nitride layer or an oxidized nitride layer. A silicon oxide layer may be formed between the semiconductor substrate 100 and the hard mask to buffer a stress applied to the semiconductor substrate 100.

A trench is formed by etching the semiconductor substrate 100 using the hard mask as an etch mask. Next, a device isolation insulating layer is formed to fill the trench and then the device isolation insulating layer may be planarized to form a device isolation layer 101. The device isolation layer 101 defines a plurality of active regions ACT1 at the cell region CR and a peripheral active region ACT2 at the peripheral region PR. The device isolation layer 101 may comprise a silicon oxide layer. Subsequently, the hard mask is removed.

A gate dielectric layer 110 is formed on the semiconductor substrate 100. The gate dielectric layer 110 may comprise a silicon oxide layer. The silicon oxide layer may be a thermal oxide layer formed by thermally oxidizing a surface of the semiconductor substrate 100. If a transistor that will be formed in the peripheral region PR is to be a high voltage transistor, the gate dielectric layer 110 in the peripheral region PR may be formed to have a thickness greater than that of the gate dielectric layer 110 in the cell region CR. In this case, after the gate dielectric layer 110 is formed in the cell region CR and the peripheral region PR, the gate dielectric layer 110 formed in an area for a low voltage transistor may be removed and then the gate dielectric layer for the high voltage transistor may be formed.

A lower gate layer 120 is formed on the gate dielectric layer 110. The lower gate layer 120 may comprise a polysilicon layer. The polysilicon layer may be doped with an impurity (e.g., boron). An example of the concentration of boron is 4×10²⁰ atoms/cm³.

A blocking insulating layer 130 is formed on the lower gate layer 120. The blocking insulating layer 130 may include at least one of a silicon oxide layer, a silicon nitride layer, Al₂O₃, hafnium aluminate, HfAlO, HfAlON, hafnium silicate, HfSiO, and HfSiON. For example, the blocking insulating layer 130 may be a silicon oxide layer having a thickness greater than that of the gate dielectric layer 110. Alternatively, the blocking insulating layer 130 may be an ONO layer (i.e., a stack of a silicon oxide layer, a silicon nitride layer, and a silicon oxide layer). As another alternative, the blocking insulating layer 130 may comprise a high-k dielectric (e.g., Al₂O₃, hafnium aluminate, HfAlO, HfAlON, hafnium silicate, HfSiO, or HfSiON) whose dielectric constant is greater than that of the gate dielectric layer 110.

A first upper gate layer 142 is formed on the blocking insulating layer 130. The first upper gate layer 142 may comprise a polysilicon layer. The first upper gate layer 142 may have a thickness of, for example, about 200 Å to 300 Å.

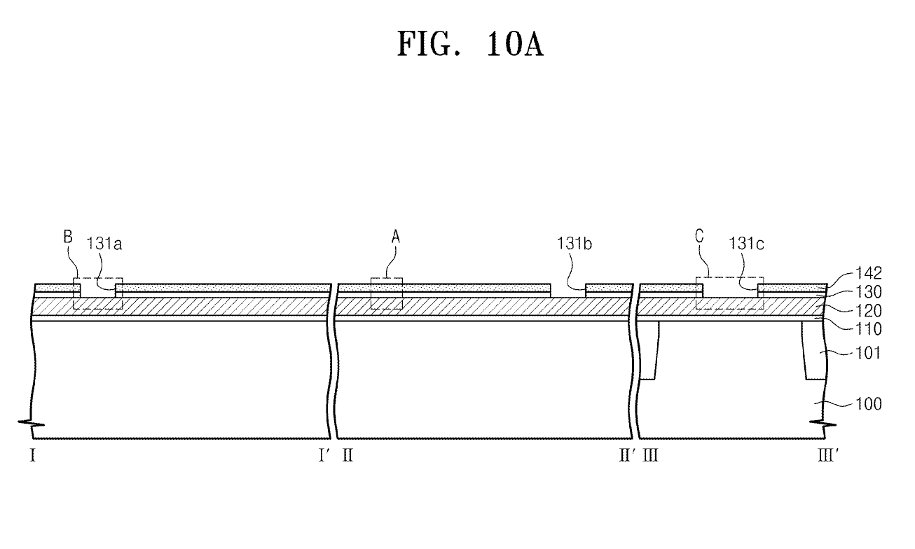

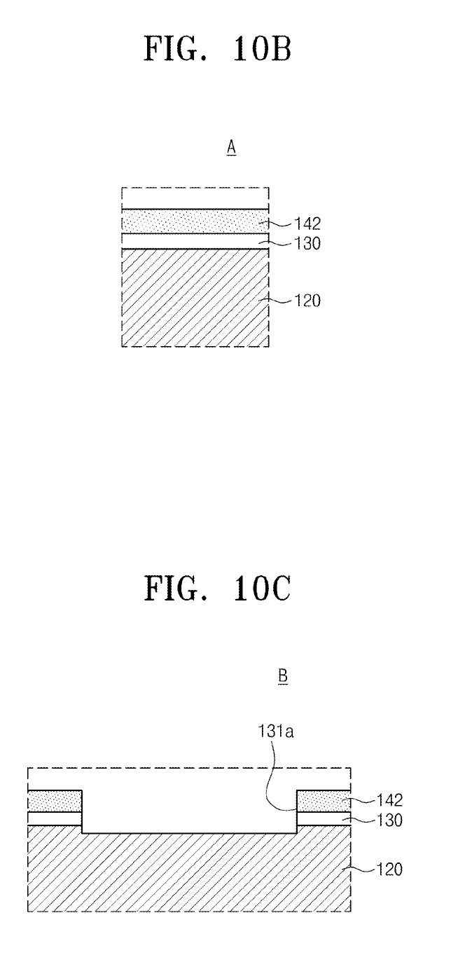

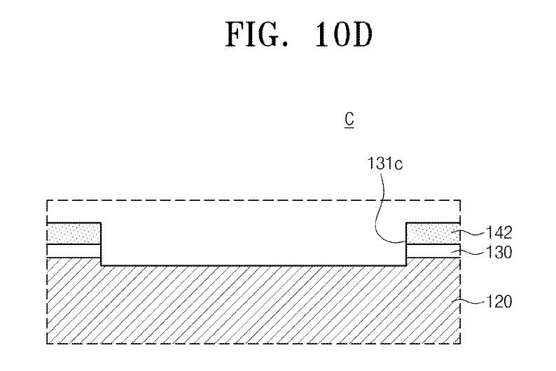

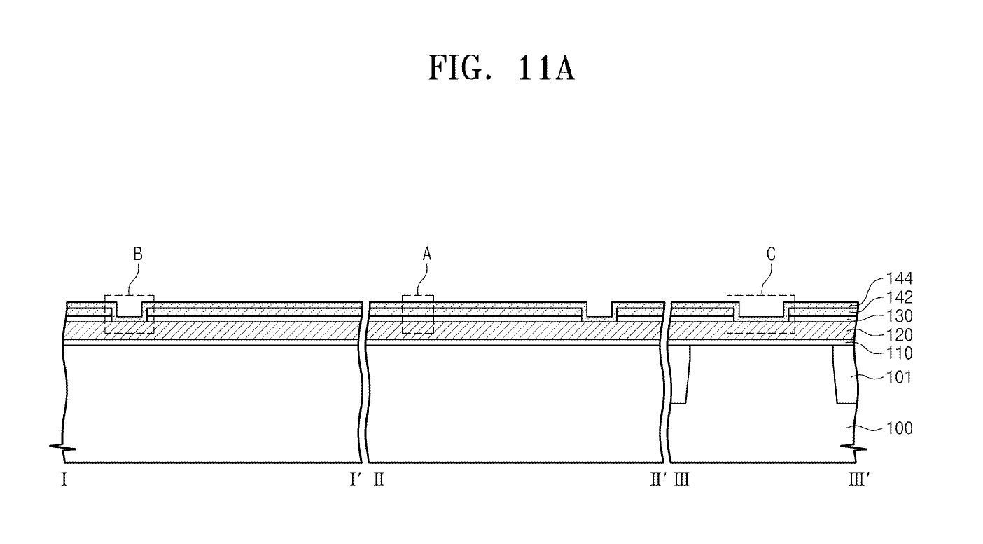

Referring to FIGS. 10A to 10D, the first upper gate layer 142 and the blocking insulating layer 130 are patterned to form first to third openings 131a, 131b, and 131c which expose the lower gate layer 120. The first and second openings 131a and 131b are formed in areas where string and ground select gates are to be formed, respectively. The third opening 131c is formed in an area where a peripheral gate is to be formed. Surfaces of the lower gate layer 120 exposed by the first to third openings 131a, 131b, and 131c may be disposed at a level lower than that of a top surface of the lower gate layer 120.

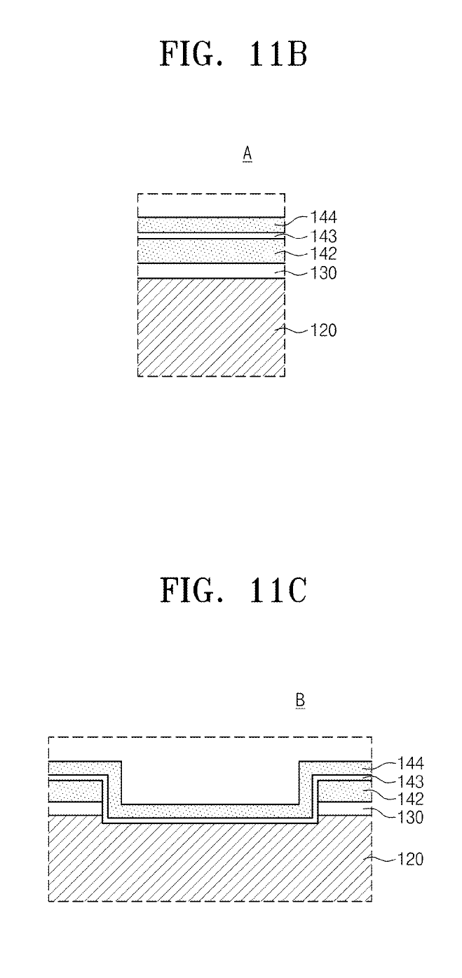

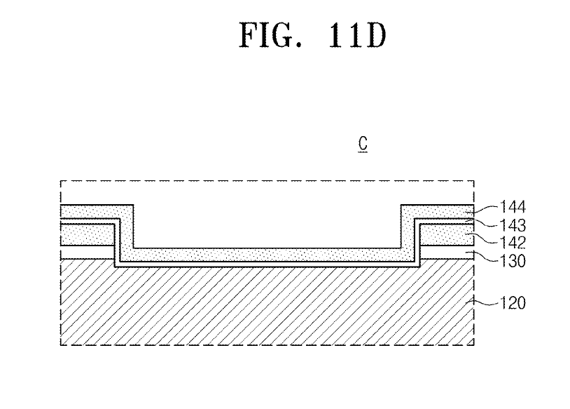

Referring to FIG. 4 and FIGS. 11A to 11D, a silicon oxide layer is then formed on top surfaces of the first upper gate layer 142 and the surfaces of the lower gate layer 120 exposed by the first to third openings 131a, 131b, and 131c. The silicon oxide layer may have a thickness of tens of Å (e.g., about 20 Å to about 40 Å). The silicon oxide layer may be a native oxide layer.

The thickness of the silicon oxide layer may then be adjusted. For example, as described before with reference to FIG. 8, a solution (e.g., 200:1 HF) may be used to adjust the thickness of the silicon oxide layer. Alternatively, the silicon oxide layer may be completely removed and thereafter a silicon oxide layer may be formed to a suitable thickness by, for example, a chemical vapor deposition process. In any case, the final silicon oxide layer 143 has a thickness of substantially 10 Å to 20 Å, preferably 10 Å to 15 Å, meaning that the adjustment process is controlled with the intent to finalize the thickness within these ranges but that the actual thicknesses may be about 10 Å to about 20 Å, preferably about 10 Å to about 15 Å. For ease of illustration, the second barrier pattern 143b is omitted in FIG. 11A.

A second upper gate layer 144 is formed on the final silicon oxide layer 143. The second upper gate layer 144 may be a polysilicon layer. The second upper gate layer 144 may be thinner than the first upper gate layer 142. The second upper gate layer 144 may have a thickness of about 100 Å or less, preferably about 50 Å or less.

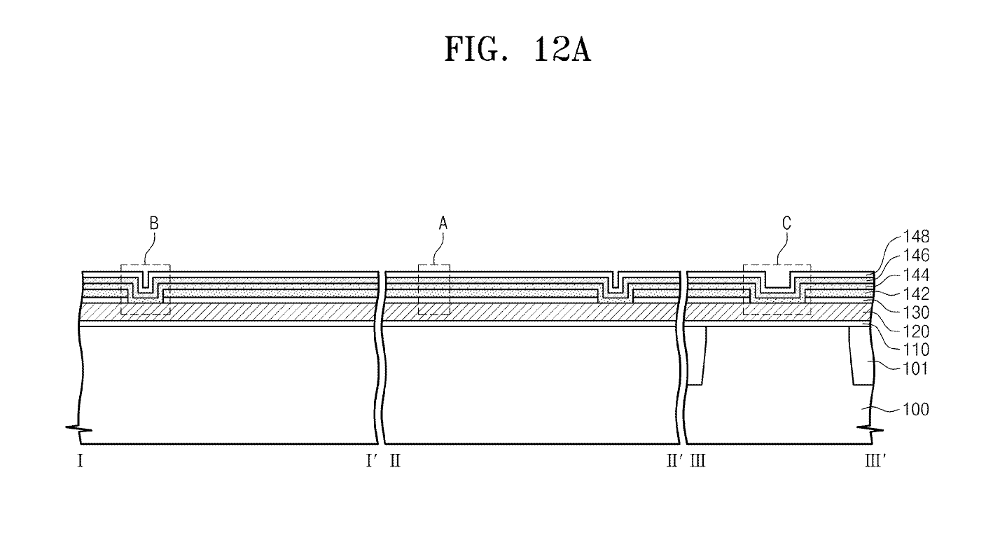

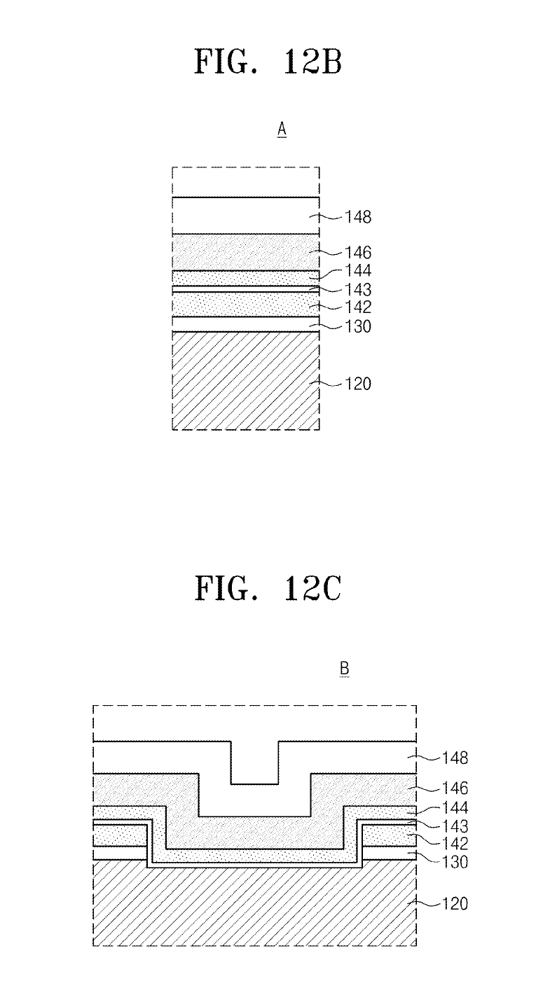

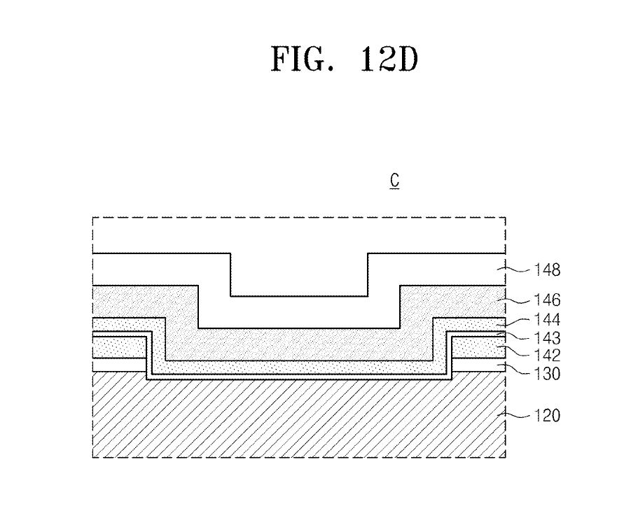

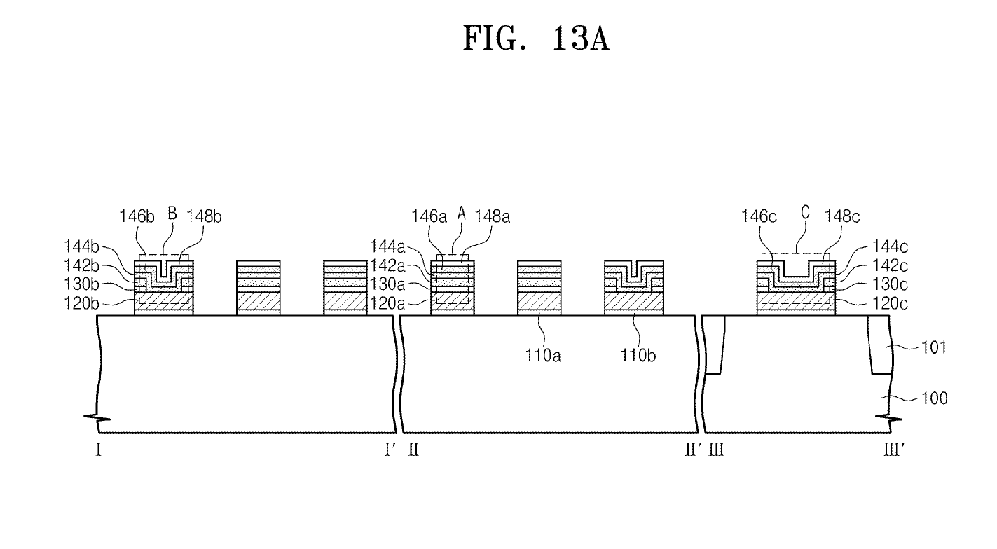

Referring to FIG. 4 and FIGS. 12A to 12D, a conductive layer 146 is formed on the second upper gate layer 144. The conductive layer 146 may include at least one of a metal (e.g., tungsten, cobalt, or molybdenum), a conductive metal nitride (e.g., tungsten nitride, titanium nitride, tantalum nitride, or molybdenum nitride), and a metal silicide (e.g., tungsten silicide or cobalt silicide). For example, the conductive layer 146 may include tungsten nitride and tungsten on the tungsten nitride. A capping layer 148 may be formed on the conductive layer 146. The capping layer 148 may be a silicon nitride layer.

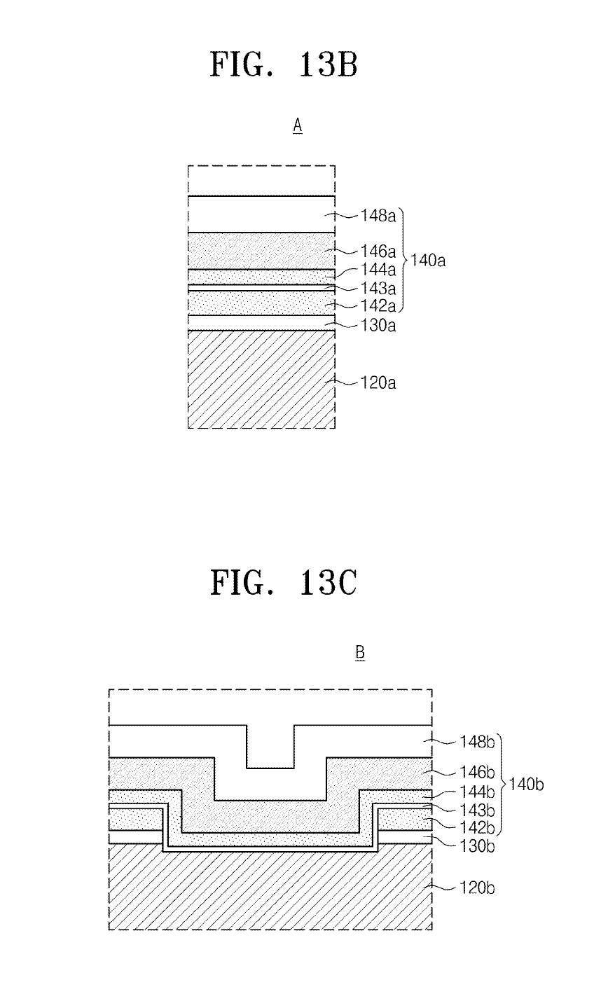

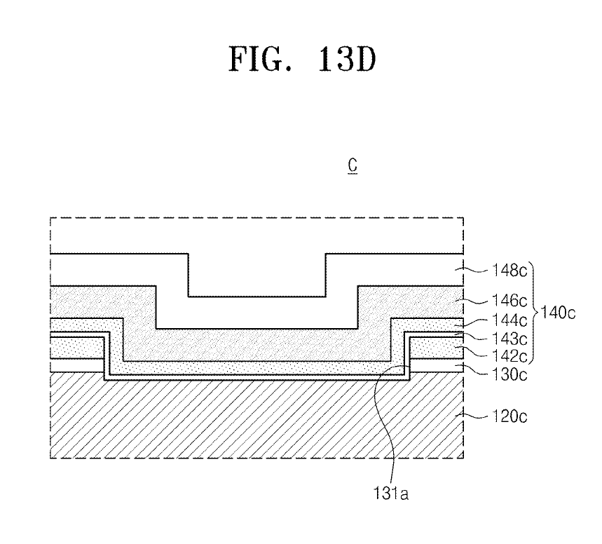

Referring to FIG. 4 and FIG. 13A to 13D, an etching process is performed to etch the gate dielectric layer 110, the lower gate layer 120, the inter-gate dielectric layer 130, the first upper gate layer 142, the silicon oxide layer 143, the second upper gate layer 144, the conductive layer 146, and the capping layer 148. As a result, a string select gate 200b, a ground select gate 200c, and memory cell gates 200a between the string select gate 200b and the ground select gate 200c are formed in the cell region CR. The string select gate 200b and the ground select gate 200c define the first opening 131a and the second opening 131b, respectively. In the peripheral region PR, there may be formed a peripheral gate 200d defining the third opening 131c.

Referring back to FIG. 4 and FIGS. 5A to 5C, sidewall spacers 150 may be formed on sidewalls of the gates 200a, 200b, 200c and 200d Impurity regions 160 may be formed in the semiconductor substrate 100 at one or both sides of at least one of the gates 200a, 200b, 200c, and 200d. For example, before or after the sidewall spacers 150 are formed, impurities may be implanted into the semiconductor substrate 100 to form the impurity regions 160 at one side (e.g., to the left) of the string select gate 200b, at one side (e.g., to the right) of the ground select gate 200c, and at both sides of the peripheral gate 200d. Additional Impurity regions may be formed in the semiconductor substrate 100 at both sides of each of the memory cell gates 200a.

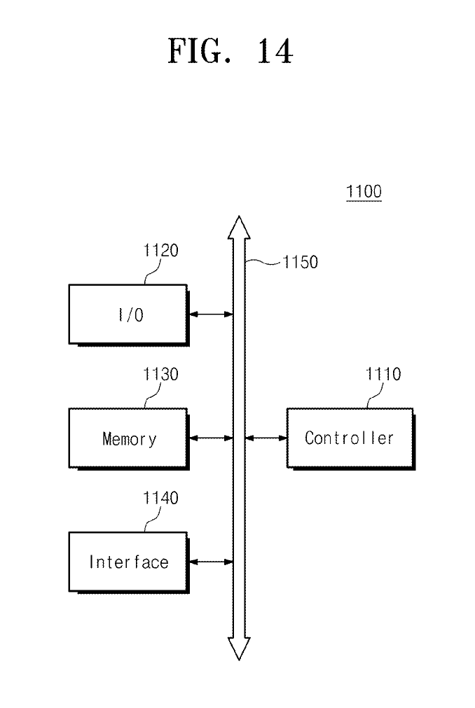

An example of an electronic system 1100 including a nonvolatile memory device according to the inventive concept will now be described in detail with reference to FIG. 14.

The electronic system 1100 may include a controller 1110, an input/output (I/O) device 1120, a memory 1130, an interface 1140, and a bus 1150. The controller 1110, the I/O device 1120, the memory 1130 and/or the interface 1140 may be connected to each other through the bus 1150. The bus 1150 provides a data transfer path. The memory 1130 comprises a nonvolatile memory device according to the inventive concept.

The controller 1110 may include at least one of a microprocessor, a digital signal processor, a microcontroller, and the like. The I/O device 1120 may include a keypad, a keyboard, a display device, etc. The memory 1130 may store data and/or commands. The interface 1140 may communicate with a communication network. The interface 1140 may be wired or configured to be wireless. For example, the interface 1140 may comprise antennas, wire/wireless transceivers, etc. The electronic system 1100 may further include a high speed DRAM and/or an SRAM as an operating memory to improve the operation of the controller 1110.

The electronic system 1100 may be employed by personal digital assistants (PDAs), portable computers, web tablets, wireless phones, mobile phones, digital music players, memory cards or any other type of device capable of transmitting and/or receiving data in a wireless manner.

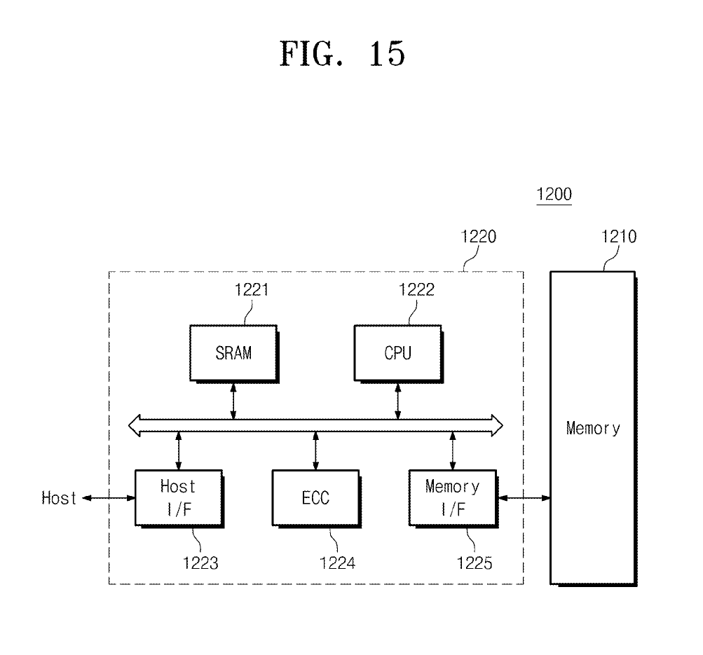

An example of a memory system 1200 including a nonvolatile memory device according to the inventive concept will now be described in detail with reference to FIG. 15.

The memory system 1200 has a memory 1210 including a nonvolatile memory device according to the inventive concept. The memory 1210 may also include different types of memory devices (e.g., a DRAM and/or SRAM). The memory system 1200 may also include a memory controller 1220 configured to control data exchange between a host and the memory 1210.

The memory controller 1220 may include a central processing unit 1222 controlling the overall operation of the memory system 1200. The memory controller 1220 may further include an SRAM 1221 used as a working memory of the central processing unit 1222. The memory controller 1222 may further include a host interface 1223 and a memory interface 1225. The host interface 1223 may establish a data exchange protocol between the host and the memory system 1200. The memory interface 1225 may connect the memory controller 1220 and the memory 1210 to each other. Furthermore, the memory controller 1220 may further include an error correction code (ECC) block 1224. The error correction code block 1224 may detect and correct errors included in data read from the memory 1210. Although not shown in this figure, the memory system 1200 may further include a ROM storing code for interfacing with the host. The memory system 1200 may be embodied as a portable data storage card. Alternatively, the memory system 1200 may also be embodied as a solid state drive (SSD) as a substitute for the hard disk of a computer system.

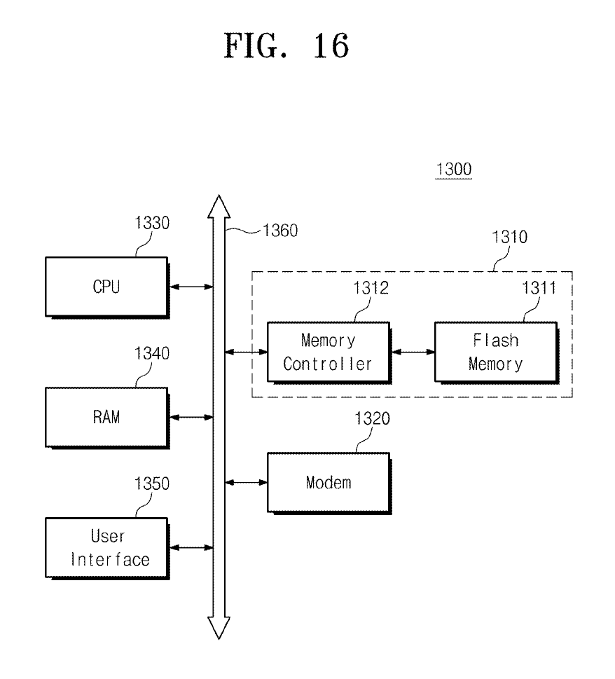

An example of a data processing system 1300 including a nonvolatile memory device according to the inventive concept will now be described in detail with reference to FIG. 16. The data processing system 1300 may be embodied as a mobile device or a desktop computer.

The data processing system 1300 includes a flash memory system 1310, a modem 1320, a central processing unit 1330, a RAM 1340, and a user interface 1350 that are connected to a system bus 1360. The flash memory system 1310 may be similar to the above-described memory system 1200 of FIG. 15. The flash memory system 1310 stores data processed by the central processing unit 1330 or data inputted from an external device. The memory system 1310 may be configured as a solid state drive (SSD) and in this case, the data processing system 1300 can stably store large amounts of data in the flash memory system 1310. As reliability is improved, the flash memory system 1310 can reduce resources used to correct errors, thereby providing a high-speed data exchange function to the data processing system 1300. Even though not depicted in this drawing, it will be apparent to one of ordinary skill in the art that the data processing system 1300 may further include an application chipset, a camera image processor (CIS), and an input/output device.

According to an aspect of the inventive concept as described above, a nonvolatile memory device can prevent boron of a lower gate structure, such as that of a select, memory cell or peripheral transistor of a nonvolatile memory device, from diffusing into a metal of a conductive layer (e.g., a tungsten layer), thereby suppressing the formation of high resistive material. The resistance characteristics of select and peripheral gates are thus improved such that the operation speed of the nonvolatile memory device can be increased.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

1. A nonvolatile memory device comprising:
a semiconductor substrate;
select gates on the semiconductor substrate; and
cell gates on the semiconductor substrate, the cell gates being interposed between the select gates, and
wherein each of the cell gates includes:
a tunnel insulating pattern on the semiconductor substrate,
a floating gate on the tunnel insulating pattern,
a blocking insulating pattern on the floating gate, and
a control gate on the blocking insulating pattern, and
wherein the control gate includes:
a first control gate pattern,
a second control gate pattern on the first control gate pattern,
a cell conductive pattern on the second control gate pattern, and
a barrier pattern interposed between the first control gate pattern and the second control gate pattern.

2. The memory device of claim 1, wherein the barrier pattern comprises a silicon oxide layer and has a thickness of substantially 10 Å to 20 Å.

3. The memory device of claim 1, wherein the first control gate pattern has a thickness greater than that of the second control gate pattern.

4. The memory device of claim 3, wherein the second control gate pattern has a thickness of 100 Å or less.

5. The memory device of claim 1, wherein the floating gate pattern comprises a polysilicon layer including boron as an impurity.

6. The memory device of claim 5, wherein the first and second control gate patterns each comprise a polysilicon layer and the cell conductive pattern comprises tungsten.

7. The memory device of claim 1, wherein each of the select gates comprises:
a lower gate pattern on the semiconductor substrate;
a gate dielectric pattern interposed between the lower gate pattern and the semiconductor substrate;
an inter-gate dielectric pattern and a first upper gate pattern stacked on the lower gate pattern, the inter-gate dielectric pattern and the first upper gate pattern defining an opening leading to the lower gate pattern;
a second upper gate pattern on the first upper gate pattern; and
a select conductive pattern on the second upper gate pattern, and
wherein the second upper gate pattern and the select conductive pattern protrude into the opening, and the barrier pattern is interposed between the lower gate pattern and the second upper gate pattern.

8. The memory device of claim 7, wherein the barrier pattern extends between the first upper gate pattern and the second upper gate pattern.

9. The memory device of claim 7, wherein a lower surface of the second upper gate pattern is disposed at a level in the device beneath that at which an upper surface of the inter-gate dielectric pattern is disposed.

10. The memory device of claim 7, wherein each of the blocking insulating pattern and the inter-gate dielectric layer comprises a silicon oxide layer, a silicon nitride layer, and a silicon oxide layer that are stacked one on another.

11. The memory device of claim 7, wherein the floating gate pattern, the blocking insulating pattern, the first control gate pattern, the second control gate pattern, and the cell conductive pattern are of the same materials as the lower gate pattern, the inter-gate dielectric pattern, the first upper gate pattern, the second upper gate pattern, and the select conductive pattern, respectively.

12. A nonvolatile memory device comprising:
a semiconductor substrate;
a lower gate pattern on the semiconductor substrate;
a gate dielectric pattern interposed between the lower gate pattern and the semiconductor substrate;
an inter-gate dielectric pattern and a first upper gate pattern stacked on the lower gate pattern, the inter-gate dielectric pattern and the first upper gate pattern defining an opening leading to the lower gate pattern;
a second upper gate pattern on the first upper gate pattern; and
a conductive pattern on the second upper gate pattern, and
wherein the second upper gate pattern and the conductive pattern protrude into the opening, and the barrier pattern is interposed between the lower gate pattern and the second upper gate pattern.

13. A nonvolatile memory device comprising a plurality of cell strings in a cell region of the device, and a peripheral transistor in a peripheral region of the device located outside the cell region,
wherein the cell strings include memory cell transistors and select transistors,
the transistors are constituted by gate structures, and the gate structures of the memory cell and select transistors are disposed in an array on a semiconductor substrate, and
the gate structure of each of at least one of the memory cell transistors, the select transistors and the peripheral transistor comprises:
a gate dielectric layer disposed on the semiconductor substrate,
a lower gate structure disposed on the gate dielectric layer, the lower gate structure comprising a polysilicon layer containing a dopant, and
an upper gate structure disposed on the polysilicon layer,
the upper gate structure including a first upper gate layer, a second upper gate layer, a silicon oxide layer interposed between the first and second upper gate layers, and a conductive layer comprising a metal disposed on the second upper gate layer.

14. The memory device of claim 13, wherein the gate structure of each of the memory cell transistors comprises the gate dielectric layer, lower gate structure, and upper gate structure, and further comprises a blocking insulating pattern between the floating gate and the control gate,
the gate dielectric layer constitutes a tunnel insulating pattern of the memory cell transistor,
the lower gate structure constitutes a floating gate on the tunnel insulating pattern, and
the upper gate structure constitutes a control gate.

15. The memory device of claim 13, wherein the gate structure of each of the select transistors and the peripheral transistor comprises the gate dielectric layer, lower gate structure, and upper gate structure, and further comprises an inter-gate dielectric pattern interposed between the lower gate structure and the upper gate structure,
the inter-gate dielectric pattern and the first upper gate layer define an opening leading to the lower gate structure, and
the second upper gate layer and the conductive layer protrude into the opening.

16. The memory device of claim 13, wherein the dopant is boron.

17. The memory device of claim 16, wherein the metal of the conductive layer comprises tungsten.

18. The memory device of claim 13, wherein the silicon oxide layer has a thickness of substantially 10 Å to 20 Å.

19. The memory device of claim 18, wherein the dopant is boron.

20. The memory device of claim 19, wherein the metal of the conductive layer comprises tungsten.

21-27. (canceled)
